(19) United States
(12) Patent Application Publication
(10) Pub. No.: US 2010/0156440 A1
(43) Pub. Date: Jun. 24, 2010

(54) Anti-Pinch Sensor

(75) Inventors: Thomas Weingärtner, Memmelsdorf (DE); Thorsten Kuhnen, Kitzingen (DE); Holger Würstlein, Zeil am Main (DE)

Correspondence Address: KING & SPALDING, 1185 AVENUE OF THE AMERICAS, NEW YORK, NY, 10036-4003, US

(73) Assignee: BROSE FAHRZEUGTEILE GMBH & Co., Coburg (DE)

(21) Appl. No.: 12/063,427

(22) PCT Filed: Jun. 30, 2006
(86) PCT No.: PCT/EP06/06380

§ 371 Date: Mar. 25, 2008

(30) Foreign Application Priority Data
Aug. 11, 2005 (DE) 20 2005 012 636.5

(51) Int. Cl. G01R 27/26

(52) U.S. Cl. 324/658

(57) ABSTRACT

The invention relates to an anti-pinch sensor (10, 13, 36), in particular for recognising an obstacle that obstructs an actuating element (7) of a motor vehicle (1). Said sensor comprises an electrode (17), which can be attached to a measuring potential via a signal line (26) and can be positioned opposite a counter-electrode (25) and comprises an evaluation circuit (34) for detecting the capacitance between the electrode (17) and the counter-electrode (25). The electrode (17) is sub-divided into several electrodes (35), each of which has a separate feed line (23) for connection to the measuring potential. An anti-pinch sensor of this type (10, 13, 36) has a high detection sensitivity.

The invention relates to an anti-pinch sensor, in particular for detecting an obstacle in the path of an actuator element of a motor vehicle, having an electrode which can be connected to a measurement potential via a signal line and can be positioned opposite a corresponding electrode, and having an evaluation circuit for detecting the capacitance between the electrode and corresponding electrode.

In such a sensor, an electrical field is generated between the electrode and the corresponding electrode. If a dielectric or generally an object with a relative dielectric constant ∈ᵣ of greater than 1 enters this field, as a result the capacitance formed by the electrode and corresponding electrode changes. Therefore, if the capacitance between the electrode and the corresponding electrode is measured with a suitable evaluation circuit, as a result an obstacle located in the path of an actuator element of a motor vehicle can be detected and corresponding countermeasures can be taken.

An anti-pinch sensor of the type mentioned at the beginning is suitable in particular for detecting obstacles in closing elements of a motor vehicle, for example a window which can be activated electrically, a sliding door which can be activated electrically or a tailgate which can be activated electrically. Such an anti-pinch sensor can also be used to detect obstacles in the case of a seat which can be activated electrically.

A sensor of the type mentioned at the beginning is known, for example, from DE 102 20 725 C1. In said document, a shielding electrode is located between the electrode which generates the electrical field and the actuator means. The shielding electrode fulfils here the purpose of reducing the influence of the movable actuator element on the capacitive measurement signal. The shielding electrode is electrically insulated and has a conductive face which is composed of an electrically conductive material. As a result, the electrical field which is generated by the electrode does not extend beyond the shielding electrode, with the result that an actuator element which can move beyond the shielding electrode cannot influence the capacitance of the arrangement.

The anti-pinch sensor must disadvantageously be integrated into the vehicle in a costly way. In particular, embedding of the shielding electrode into the seal which seals the actuator element is described.

The object of the invention is to specify an anti-pinch sensor which is easy to integrate into a vehicle and which additionally has a high detection sensitivity.

This object is achieved according to the invention for an anti-pinch sensor of the type mentioned at the beginning by virtue of the fact that the electrode is divided into a plurality of separate electrodes which each have a separate feed line for connection to the measurement potential.

The invention is based initially in a first step on the idea that the change in capacitance caused by a foreign body penetrating the path of an actuator element is usually small. Such a change in the capacitance can, however, be detected better the smaller the overall capacitance which is formed between the electrode and corresponding electrode.

In a second step, the invention recognizes that the capacitance which is formed between the electrode and the corresponding electrode can be reduced by virtue of the fact that an electrode is used which is divided into a plurality of individual electrodes. As a result, the capacitance which is formed with the corresponding electrode is reduced. This is due to the fact that the entire surface of the electrode is divided into a plurality of interrupted individual faces of the individual electrodes, which correspondingly reduces the capacitance.

An anti-pinch sensor which is configured in such a way permits a change in capacitance to be detected by means of a multiplex method. In this context, the individual electrodes can be actuated, by means of the separate feed lines, either with a chronological offset (serially) or simultaneously (in parallel). The first serial actuation provides the advantage that in this context only a single evaluation circuit is necessary to change the capacitance.

However, it is necessary here to comply with the timing constant until all the electrodes have been connected through in succession. Although the second parallel actuation does not have the disadvantageous delay, a plurality of electronic evaluation systems are required for the evaluation, which increases the costs.

In one advantageous embodiment of the invention, the electrode (17) extends in a longitudinal direction and is divided into the plurality of separate electrodes (35) in the longitudinal direction. This makes it possible to make the anti-pinch sensor extend along an anti-pinch area. This also makes it possible, when there is serial actuation of the individual electrodes, to sense parameters of an obstacle located in the path of the actuator element, such as for example its size or position.

The electrode is advantageously made to extend in a flexible carrier. Such a carrier permits adaptation of the anti-pinch sensor to the given contours of a motor vehicle.

It is also advantageous if a shielding electrode is additionally provided, and the electrode and the shielding electrode are arranged essentially one opposite the other and are insulated from one another. If such a shielding electrode is introduced between the electrode and corresponding electrode, the electrical field which is formed between the electrode and shielding electrode can be reduced. On the other hand, a high capacitance is produced between the shielding electrode and the corresponding electrode. In this context, the edge areas of the electrode which are not covered and the corresponding electrode continue to form a capacitance which, however, is significantly reduced owing to the effective surface area of the electrode which is drastically reduced by the shielding electrode. In addition, as a result of this embodiment, an electrical field which is directed far into the space is formed between the electrode and the corresponding electrode.

In order to produce the described effect, the shielding electrode is arranged essentially opposite the electrode in the anti-pinch sensor. In this way, the anti-pinch sensor can easily be integrated into a motor vehicle in which it is arranged opposite the bodywork of the motor vehicle in such a way that the shielding electrode lies between the electrode and the bodywork.

As a result of the common guidance in a flexible carrier, the shielding sensor can be made to extend along any desired contours of the motor vehicle without the configuration of the anti-pinch sensor itself having to be adapted for this purpose.

The shielding electrode is expediently divided into individual electrodes with which there is electrical contact and between which the separate feed lines are arranged in an insulated fashion. This reliably avoids a capacitance being formed between the feed lines and the corresponding electrode. Each feed line is shielded in this way with respect to the corresponding electrode.

Furthermore, a switching means is advantageously provided for approximating the potential between the electrode and the shielding electrode. This ensures that an electrical field is not formed between the electrode and shielding electrode. Correspondingly, the capacitance formed by the electrode and corresponding electrode is reduced further.

In order to approximate the potential, an amplifier is expediently provided which is connected at the output end to the shielding electrode in order to supply it with a signal which is derived from the signal line. This ensures in a simple way that the shielding electrode is always at the same potential as the electrode. A change in the capacitance owing to fluctuations in potential between the electrode and the shielding electrode is reliably avoided in this way. It is particularly favorable here to actuate the shielding electrode with a low impedance.

In one advantageous embodiment, a ribbon cable or a round cable is used as the carrier for the electrode and the shielding electrode. Such cables are in particular embodied with multiple conductors, are cost effective and are available in many designs. In order to form the anti-pinch sensor, the lines which are present in such cables are used here both as signal lines and as electrodes and corresponding electrodes.

In a further advantageous alternative, a flexible printed circuit board is used as the carrier of the electrode and the shielding electrode. In this context, the electrode and the shielding electrode as well as the feed lines and signal lines which are necessary for them are respectively embodied as conductor tracks in a printed circuit board having a plurality of layers. The printed circuit board material itself is here a flexible plastic. Such an embodiment provides the large advantage of the possibility of configuring the shape of the electrode and shielding electrode relatively freely. It is also possible to make the flexible printed circuit board relatively flat, as a result of which it can easily be made to extend along contours of a motor vehicle.

The anti-pinch sensor can easily be used to detect an obstacle in the path of an actuator element of a motor vehicle if the grounded bodywork of the motor vehicle serves as the corresponding electrode. For this purpose, the described anti-pinch sensor is made to extend along contours of the motor vehicle in such a way that the shielding electrode comes to rest between the bodywork and the electrode. The evaluation circuit detects here the capacitance which is formed between the electrode and the grounded bodywork.

Exemplary embodiments of the invention are explained in more detail with reference to a drawing, in which:

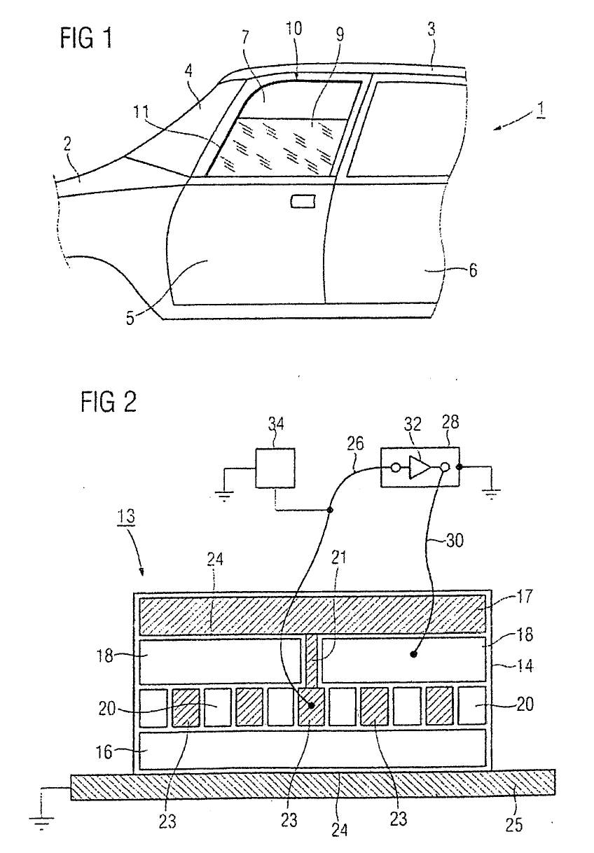

FIG. 1 is a schematic side view of a motor vehicle,

FIG. 2 is a cross-sectional view of an anti-pinch sensor which is implemented by a flexible printed circuit board,

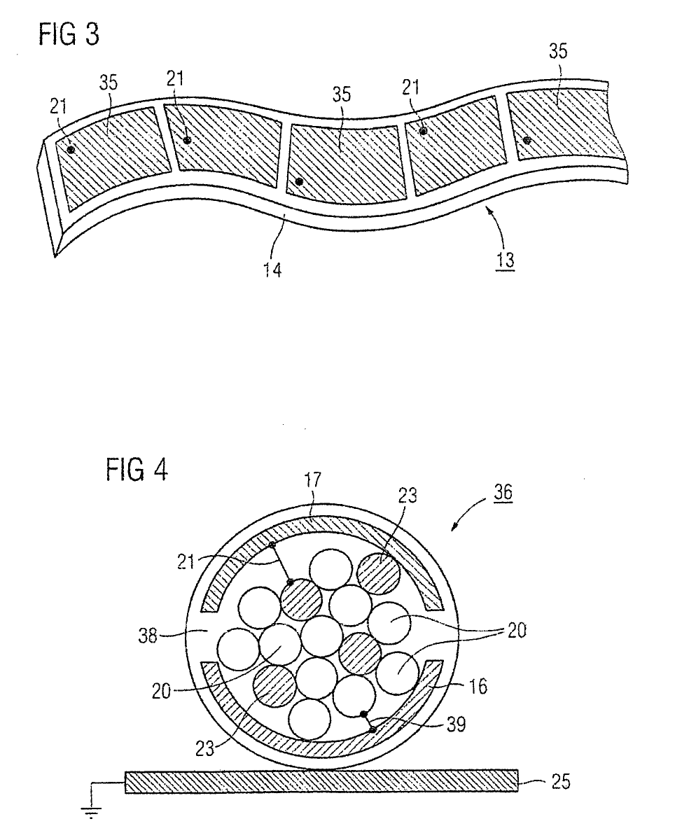

FIG. 3 is a plan view of the anti-pinch sensor according to FIG. 2, and

FIG. 4 is a cross-sectional view of an anti-pinch sensor which is implemented by means of a round cable.

FIG. 1 is a schematic side view of a motor vehicle 1, whose engine hood 2, roof 3 and windshield 4 can be seen. A front door 5 and a rear door 6 are also illustrated.

The front door 5 has an electrically driven window pane 9 as actuator element 7. When the window pane 9 closes, it is necessary to ensure that there is no obstacle located in the range of movement of the window pane 9. For this purpose, an anti-pinch sensor 10, which is embodied as a ribbon cable 11, is mounted along the front and upper inner contour of the door 5. In the ribbon cable 11 there are a plurality of electrodes (not illustrated here) which are separated from one another and have separate feed lines for actuating them. Furthermore, a shielding electrode is arranged in the ribbon cable 11 between the individual electrodes and the inner contour of the front door 5. The bodywork of the motor vehicle 1 serves as a corresponding electrode.

If an obstacle which has a relative dielectric constant of >1 is located in the range of movement of the window pane 9, this results in a change in the capacitance formed between the electrodes arranged in the ribbon cable 11 and the bodywork. If such a change in capacitance is detected, the electric drive is stopped or driven in reverse, i.e. energized in the opposing direction, by means of a control signal.

In order to describe the method of functioning, FIG. 2 illustrates a further anti-pinch sensor 13 which is configured by means of a flexible printed circuit board 14 having a plurality of layers. The lower layer of the flexible printed circuit board 14 is formed here by a shielding electrode 16 which is embodied as a planar conductor track. Opposite said shielding electrode 16 a planar conductor track is further arranged in the top layer of the printed circuit board 14 as an electrode 17. Said planar conductor track is divided multiply (not visible here) in the longitudinal direction of the printed circuit board 14. In turn, an individual electrode 18 which serves for shielding purposes and which is electrically conductively connected to the shielding electrode 16 is formed as a planar conductor track below the electrode 17. In each case further individual electrodes 20 which serve for shielding purposes and electric feed lines 23 which serve to make contact with the individual electrodes which are produced by dividing the electrode 17 are now arranged alternately in the layer between the individual electrode 18 and the shielding electrode 16. This can be seen clearly in the illustrated section, and electric contact is made here with the centrally arranged electrical feed line 23 via the through-contact 21 with the electrode 17 arranged above it. In order to form a through-contact, the individual electrode 18 has a breakthrough at a corresponding point. All the illustrated conductor tracks are each insulated from one another by the insulation material 24 of the printed circuit board 14.

In order to detect an obstacle in the path of an actuator element, the anti-pinch sensor 13 of a grounded corresponding electrode 25 is fitted on, and said corresponding electrode 25 can be formed, for example, by the bodywork of a vehicle. In order to measure a change in capacitance caused by an obstacle, an alternating voltage is applied to the electrode 17 by means of the signal line 26, the corresponding feed line 23 and the through-contact 21. The alternating voltage is generated here with respect to the ground potential by means of a signal generator 28. Furthermore, the connecting line 30 is used to apply an alternating voltage, derived from the alternating voltage fed to the electrode 17, to the individual electrodes 18, 20 which serve for shielding purposes, and to the shielding electrode 16. For this purpose, a switching means 32 which is embodied as an operational amplifier is inserted between the signal line 26 and the connecting line 30. This ensures that the electrodes 18 and 20 which serve for shielding purposes and the shielding electrode 16 are at the same potential as the electrode 17 without a delay.

Owing to the individual electrodes 18 and 20 which are at the same potential and the shielding electrode 16, there is no direct capacitance between the electrode 17 and the corresponding electrode 25. Said capacitance is formed directly by the shielding electrode 16 and the corresponding electrode 25. Instead, an electrical field which projects far into the space is produced between the edges of the electrode 17 and the corresponding electrode 25, as a result of which a large space is available for the detection of obstacles. In this context, the capacitance which is formed by the edges of the electrode 17 and the corresponding electrode 25 is significantly reduced compared to a direct capacitance owing to the shielding effect by the individual electrodes 18 and 20 and the shielding electrode 16.

In order to measure the change in capacitance, an evaluation circuit 34 is arranged between the signal line 26 and the ground potential. This evaluation circuit 34 detects the ratio of the change in capacitance ΔC to the capacitance C. Since the capacitance C is low, a small change ΔC in capacitance ΔC can be detected. In order to detect the capacitance, either a measuring bridge can be used or the charging constant can be observed. Commercially available electronic modules which are already prefabricated for this purpose can also be used.

In FIG. 3, the anti-pinch sensor 13 which is shown in cross section in FIG. 2 is illustrated in a plan view. It is possible to see here the flexible printed circuit board 14 which can easily be made to extend along a contour of a motor vehicle. In order to clarify the design, the insulation material is removed or is not included in the drawing on the upper side of the anti-pinch sensor 13. For this reason, the individual electrodes 35 which are interrupted in the longitudinal direction of the flexible printed circuit board 14 are clearly visible. Each of these individual electrodes 35 has a through-contact 21 which is connected to a separate feed line. In this way, a multiplex method can be applied for the evaluation of the anti-pinch sensor 13. With the signal generator 28 illustrated in FIG. 2 and the evaluation circuit 34, the individual electrodes 35 are actuated individually in succession with a chronological offset and the capacitance which is formed as a result is sensed. Owing to the reduced surface area of the individual electrodes 35 compared to a conductor track which has a continuous extent, the capacitance between the electrodes 35 and the corresponding electrode 25 is reduced further. This permits a further increase in the detection sensitivity.

FIG. 4 illustrates a further alternative of an anti-pinch sensor 36 which is embodied in the form of a round cable 38. An electrode 17 and a shielding electrode 16 are arranged in half shell form in the round cable. In this context, the round cable 38 is arranged opposite a corresponding electrode 25 in such a way that the shielding electrode 16 is located between the electrode 17 and the corresponding electrode 25.

The electrode 17 is in turn divided into a plurality of individual electrodes in the longitudinal direction of the round cable 38. In order to actuate the individual electrodes, a plurality of electric feed lines 23 which are insulated from one another are provided in the interior of the round cable 38. These feed lines 23 are each respectively embodied as insulated copper cables. Further insulated copper lines, around the feed lines 23, are used as individual electrodes which serve for shielding purposes and which are connected to the shielding electrode 16 by means of an electrical connection 39. As illustrated, contact is made with the individual electrodes via a through-contact 21, in each case using the corresponding electric feed line 23.

The method of functioning and the possibilities for the detection of a change in capacitance of the shielding sensor 36 which is caused by an obstacle are identical to the shielding sensor 13 shown in FIGS. 2 and 3.

### LIST OF REFERENCE NUMERALS

1 Motor vehicle
2 Engine hood
3 Roof
4 Windshield
5 Door, front
6 Door, rear
7 Actuator element
9 Window pane
10 Anti-pinch sensor
11 Ribbon cable
13 Anti-pinch sensor
14 Printed circuit board
16 Shielding electrode
17 Electrode
18 Individual electrode
20 Individual electrodes
21 Through-contact
23 Feed lines
24 Insulating material
25 Corresponding electrode
26 Signal line
28 Signal generator
30 Connecting line
32 Switching means
34 Evaluation circuit
35 Separate electrodes
36 Anti-pinch sensor
38 Round cable
39 Connection

1. An anti-pinch sensor (10, 13, 36), in particular for detecting an obstacle in the path of an actuator element (7) of a motor vehicle (1), having an electrode (17) which can be connected to a measurement potential via a signal line (26) and can be positioned opposite a corresponding electrode (25), and having an evaluation circuit (34) for detecting the capacitance between the electrode (17) and corresponding electrode (25), wherein the electrode (17) is divided into a plurality of separate electrodes (35) which each have a separate feed line (23) for connection to the measurement potential.

2. The anti-pinch sensor (10, 13, 36) as claimed in claim 1, wherein the electrode (17) extends in a longitudinal direction and is divided into the plurality of separate electrodes (35) in the longitudinal direction.

3. The anti-pinch sensor (10, 13, 36) as claimed in claim 1 or 2, wherein the electrode (17) is made to extend in a flexible carrier.

4. The anti-pinch sensor (10, 13, 36) as claimed in one of the preceding claims, wherein a shielding electrode (16) is additionally provided, and wherein the electrode (17) and the shielding electrode (16) are arranged essentially one opposite the other and are insulated from one another.

5. The anti-pinch sensor as claimed in claim 4, wherein the electrode (17) and the shielding electrode (16) are made to extend in a flexible carrier.

6. The anti-pinch sensor as claimed in claim 4 or 5, wherein the shielding electrode (16) is divided into individual electrodes (18, 20) with which there is electrical contact and between which the separate feed lines (23) are arranged in an insulated fashion.

7. The anti-pinch sensor (10, 13, 36) as claimed in one of claims 4 to 6, wherein switching means (32) are provided for approximating the potential between the electrode (17) and the shielding electrode (16).

8. The anti-pinch sensor (10, 13, 36) as claimed in one of claims 4 to 7, wherein, in order to approximate the potential, an amplifier is provided which is connected at the output end to the shielding electrode (16) in order to supply it with a signal which is derived from the signal line (26).

9. The anti-pinch sensor (10, 13, 36) as claimed in one of claims 2 to 8, wherein a ribbon cable (11) or a round cable (38) is used as the carrier.

10. The anti-pinch sensor (10, 13, 36) as claimed in one of claims 2 to 8, wherein a flexible printed circuit board (14) is used as the carrier.

11. The use of an anti-pinch sensor (10, 13, 36) as claimed in one of the preceding claims in a motor vehicle (1), wherein the grounded bodywork of the motor vehicle (1) serves as the corresponding electrode (25).
